(19) United States
(12) Patent Application Publication
(10) Pub. No.: US 2026/0082873 A1
(43) Pub. Date: Mar. 19, 2026

(54) SUBSTRATE PROCESSING METHOD, MANUFACTURING METHOD, AND SUBSTRATE PROCESSING APPARATUS

(71) Applicant: SEMES CO., LTD., Cheonan-si (KR)

(72) Inventors: Yu Jin CHO, Suwon-si (KR); Ki Hoon CHOI, Cheonan-si (KR); Hyun YOON, Seoul (KR)

(73) Assignee: SEMES CO., LTD., Cheonan-si (KR)

(21) Appl. No.: 19/331,658

(22) Filed: Sep. 17, 2025

(30) Foreign Application Priority Data
Sep. 19, 2024 (KR) 10-2024-0126915

(51) Int. Cl. H01L 21/3105; H01L 21/67

(52) U.S. Cl. CPC H10P 95/08; H10P 72/0426

(57) ABSTRACT

Provided is a method of processing a substrate. The method includes supplying a treatment liquid containing oxygen atoms to a rotating substrate, and emitting, by a light source module, light to the substrate in a state where a liquid film formed by the supplied treatment liquid is in contact with the light source module to remove an organic material on the substrate.

### CROSS-REFERENCE TO RELATED APPLICATION

This application claims priority to and the benefit of Korean Patent Application No. 10-2024-0126915 filed in the Korean Intellectual Property Office on Sep. 19, 2024, the entire contents of which are incorporated herein by reference.

### TECHNICAL FIELD

The present invention relates to a substrate processing method, a manufacturing method, and a substrate processing apparatus, and more specifically, to a substrate processing method, a manufacturing method, and a substrate processing apparatus that remove a film on a substrate.

### BACKGROUND ART

In general, in the process of manufacturing a semiconductor device, various processes, such as a photo process, an etching process, a strip process, and an ion implantation process, are performed on a substrate, such as a wafer. The photo process includes a coating process of forming a photosensitive film by applying a photosensitive solution, such as a photoresist on the substrate, an exposure process of irradiating light, such as ultraviolet (UV) or extreme ultraviolet (EUV), to the photosensitive film using a mask of a specific pattern, and a developing process of forming a pattern on the substrate by removing the photosensitive film according to the pattern irradiated with light. The etching process forms a pattern on the substrate using a photoresist pattern formed on the substrate as a mask, and the etching process includes a wet etching process using a chemical solution and a dry etching process using plasma. The strip process is a process of removing the photoresist remaining on the substrate after the etching process is completed. Similar to the etching process, the strip process includes a wet strip process using a chemical solution and a dry strip process using plasma.

Meanwhile, in the existing strip process, photoresists are removed using a SPM solution (H₂SO₄+H₂O₂), which is a chemical solution used at high temperatures, such as sulfuric acid or phosphoric acid. However, when the strip process is performed using an SPM solution, the intermediate product (H₂SO₅) produced by the reaction of sulfuric acid and hydrogen peroxide has high reactivity and generates water, so there is a problem of reducing the process efficiency by diluting the concentration of the solution. In addition, hydrogen peroxide in the SPM solution is very unstable, so that there is a disadvantage that the SPM solution needs to be supplied continuously. As a result, as the amount of SPM solution used increases, the amount of waste water increases, and accordingly, the cost of treating wastewater increases, causing environmental problems.

In addition, as illustrated in FIG. 1, recently, ion implantation is performed on the surface of the photoresist (PR), and a semiconductor device manufacturing process is performed using the ion implantation-treated photoresist (PR). During ion implantation treatment on the surface of the photoresist (PR), H₂, N₂, O₂, hydrocarbons, etc. are generated as out-gassing atoms, and a C-rich crust layer (Crust) is formed on the surface of the ion implantation-treated photoresist (PR). This C-rich crust layer has a problem that it is difficult to be effectively removed with the existing SPM solution.

### SUMMARY OF THE INVENTION

The present invention has been made in an effort to provide a substrate processing method, a manufacturing method, and a substrate processing apparatus capable of effectively processing a substrate.

The present invention has also been made in an effort to provide a substrate processing method, a manufacturing method, and a substrate processing apparatus capable of effectively removing a thin film formed on a substrate.

The present invention has also been made in an effort to provide a substrate processing method, a manufacturing method, and a substrate processing apparatus capable of improving the efficiency of removing photoresists while not using a chemical solution or reducing the use of a chemical solution as much as possible when removing photoresist on a substrate.

Effects of the present disclosure are not limited to those described above and effects not stated above will be clearly understood to those skilled in the art from the specification and the accompanying drawings.

An exemplary embodiment of the present disclosure, a method of processing a substrate, the method comprising: supplying a treatment liquid containing oxygen atoms to a rotating substrate, and emitting, by a light source module, light to the substrate in a state where a liquid film formed by the supplied treatment liquid is in contact with the light source module to remove an organic material on the substrate.

According to the exemplary embodiment of the present invention, wherein the light source module may includes a UV lamp that emits the light.

According to the exemplary embodiment of the present invention, wherein the light source module includes an excimer UV lamp that may emits the light, and the excimer UV lamp emits the light in a wavelength range of 172 nm.

According to the exemplary embodiment of the present invention, wherein the excimer UV lamp may has a cross-section of a square tubular shape.

According to the exemplary embodiment of the present invention, wherein while the light source module emits the light to the substrate, the treatment liquid may be continuously supplied to the substrate.

According to the exemplary embodiment of the present invention, wherein while the light source module emits the light to the substrate, the substrate continues to rotate.

According to the exemplary embodiment of the present invention, wherein the light source module is located apart from an upper surface of the substrate while light source module emits the light, a distance between a light source, which is included in the light source module and emits the light, and the upper surface of the substrate may be 10 mm or less.

According to the exemplary embodiment of the present invention, wherein the treatment liquid is deionized water and/or ozone water, and the organic material may be a photoresist.

According to the exemplary embodiment of the present invention, wherein the organic material may be an ion-implanted photoresist.

According to the exemplary embodiment of the present invention, wherein, to control efficiency of removing the organic material, the amount of oxygen supplied to the treatment liquid may be controlled before the treatment liquid is supplied to the substrate to control the amount of dissolved oxygen in the treatment liquid.

According to the exemplary embodiment of the present invention, wherein in a case of increasing the efficiency of removing the organic material, the amount of oxygen supplied to the treatment liquid is increased, and in a case of lowering the efficiency of removing the organic material, the amount of oxygen supplied to the treatment liquid may be decreased.

An exemplary embodiment of the present disclosure, a manufacturing method, comprising: supplying a treatment liquid containing oxygen to a substrate provided with a photoresist, wherein an excimer UV lamp emits light to the treatment liquid to generate ozone and/or OH radicals, and the ozone and/or OH radicals decompose the photoresist, and the light source module that emits the light emits the light in a state of being in contact with a liquid formed by the treatment liquid.

According to the exemplary embodiment of the present invention, wherein while the light is emitted, the supply of the treatment liquid may continues to maintain the liquid film.

According to the exemplary embodiment of the present invention, wherein while the light is emitted, the substrate may continues to rotate.

According to the exemplary embodiment of the present invention, wherein the treatment liquid may be deionized water and/or ozone water.

According to the exemplary embodiment of the present invention, wherein the photoresist may be ion-implanted to form a C-rich crust layer on a surface thereof.

An exemplary embodiment of the present disclosure, an apparatus for processing a substrate, the apparatus comprising: a support unit for supporting and rotating a substrate; a nozzle unit for supplying a treatment liquid containing oxygen to the substrate supported by the support unit; a light source module for emitting light to the substrate supported by the support unit; and a controller for controlling at least one of the support unit, the nozzle, and the light source module, wherein the controller may controls the support unit, the nozzle, and the light source module to emit the light in a state where the liquid film formed by the treatment liquid supplied by the nozzle to the substrate supported by the support unit is in contact with the light source module.

According to the exemplary embodiment of the present invention, wherein the light source module may includes, a body for providing a light source space; at least one light source disposed in the light source space; and a cover for sealing the light source space so that the light source is not exposed to the treatment liquid supplied by the nozzle.

According to the exemplary embodiment of the present invention, wherein the light source module may includes at least one of: a hydrophobic coating portion provided on a lower surface of the body to prevent the treatment liquid from adhering to the body; and a reflective coating portion provided on an inner wall of the light source module to reflect the light in a direction toward the substrate placed on the support unit.

According to the exemplary embodiment of the present invention, the apparatus may further include a liquid supply unit for supplying the treatment liquid through the nozzle, wherein the liquid supply unit includes: a liquid supply source; a treatment liquid supply line for supplying deionized water and/or ozone water, which is the treatment liquid, to the liquid supply source; an oxygen supply line for supplying oxygen to the liquid supply source; and a treatment liquid transfer line for supplying the treatment liquid whose amount of dissolved oxygen is controlled by the oxygen supply line from the liquid supply source to the nozzle.

According to the exemplary embodiment of the present invention, it is possible to efficiently process the substrate.

In addition, according to the exemplary embodiment of the present invention, it is possible to effectively remove a thin film formed on a substrate.

In addition, according to the exemplary embodiment of the present invention, it is possible to improve the efficiency of removing photoresists while not using a chemical solution or reducing the use of a chemical solution as much as possible when removing photoresist on a substrate.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a cross-sectional view illustrating an example of a substrate provided with a photoresist on which a C-Rich Crust Layer is formed by ion implantation treatment.

FIG. 2 is a top plan view illustrating a substrate processing apparatus according to an embodiment of the present invention.

FIG. 3 is a cross-sectional view of a liquid treating chamber of FIG. 2 viewed from the side.

FIG. 4 is a top plan view illustrating the liquid treating chamber of FIG. 3 viewed from above.

FIG. 5 is a diagram of a light source module of the liquid treating chamber of FIG. 3 as viewed from below.

FIG. 6 is a diagram illustrating a wavelength band of light emitted by the light source module of FIG. 3.

FIGS. 7 and 8 are diagrams for describing a light irradiation effect according to a shape of a light source of FIG. 3.

FIG. 9 is a flowchart illustrating a substrate processing method according to an embodiment of the present invention.

FIG. 10 is a diagram illustrating a state of the liquid treating chamber performing a liquid supplying operation of FIG. 9.

FIG. 11 is a diagram illustrating a state of the liquid treating chamber performing a light emitting operation of FIG. 9.

FIGS. 12 and 13 are graphs illustrating an attenuation rate in a process of transmitting light energy emitted by the light source module to a substrate.

FIG. 14 is a flowchart illustrating a substrate processing method according to another embodiment of the present invention.

FIGS. 15 to 17 are diagrams for describing a light source module according to another embodiment of the present invention.

FIG. 18 is a diagram illustrating a state in which a nozzle for supplying a treatment liquid is installed instead of the light source module of the present invention.

FIG. 19 is a diagram illustrating a liquid treating chamber performing a light emitting operation according to another embodiment of the present invention.

FIG. 20 is a diagram illustrating a liquid treating chamber according to another embodiment of the present invention.

FIGS. 21 to 22 are diagrams illustrating a state in which a liquid treating chamber treats a substrate according to another embodiment.

FIG. 23 is a diagram schematically illustrating a liquid supply unit that may be provided in the substrate processing apparatus of the present invention.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

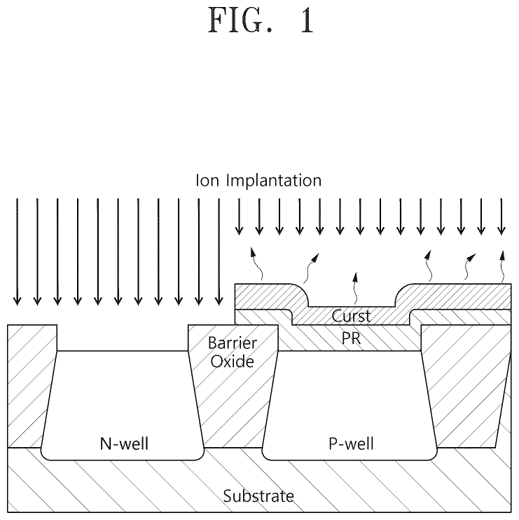

A treatment target to be described below may be a substrate, such as a wafer. In addition, a treatment target to be described below may be a substrate on which a photo process and/or an etching process have been performed. For example, a photoresist may remain on a substrate that is a treatment target. As illustrated in FIG. 1, an ion implantation treatment may be performed on a substrate that is a treatment target so that a photoresist including a C-rich carbon layer may remain. In addition, a substrate processing method described below may constitute at least a portion of a manufacturing method for manufacturing a semiconductor device.

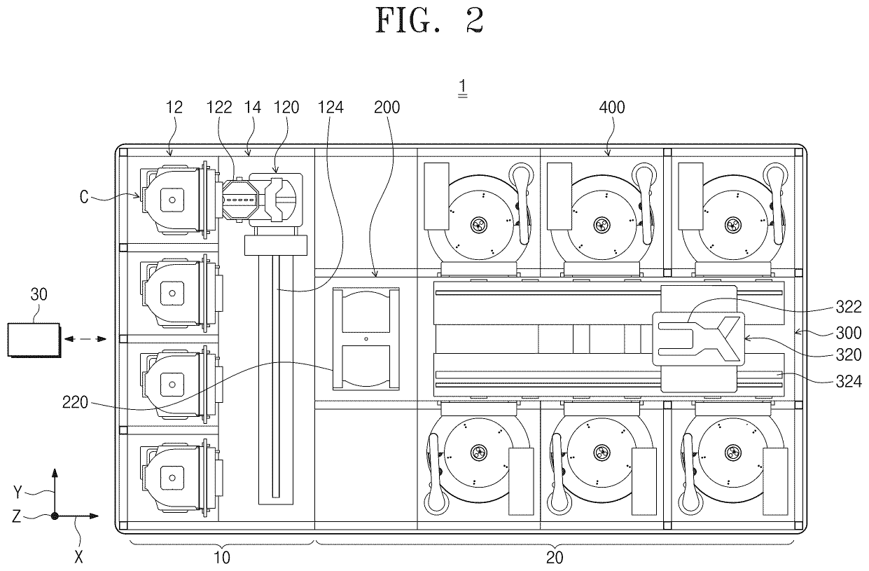

FIG. 2 is a top plan view illustrating a substrate processing apparatus according to an embodiment of the present invention.

Referring to FIG. 2, a substrate processing apparatus includes an index module 10, a treating module 20, and a controller 30. When viewed from above, the index module 10 and the treating module 20 are disposed along one direction. Hereinafter, the direction in which the index module 10 and the treating module 20 are disposed is referred to as a first direction X, and when viewed from above, a direction perpendicular to the first direction X is referred to as a second direction Y, and a direction perpendicular to both the first direction X and the second direction Y is referred to as a third direction Z.

The index module 10 transfers a substrate W from a container C in which the substrate W is accommodated to the treating module 20, and makes the substrate W, which has been completely processed in the treating module 20, be accommodated in the container C. A longitudinal direction of the index module 10 is provided in the second direction Y. The index module 10 includes a load port 12 and an index frame 14. Based on the index frame 14, the load port 12 is located at a side opposite to the treating module 20. The container C in which the substrates W are accommodated is placed in the load port 12. The load port 12 may be provided in plurality, and the plurality of load ports 12 may be disposed in the second direction Y.

As the container C, an airtight container, such as a Front Open Unified Pod (FOUP), may be used. The container C may be placed on the load port 12 by a transfer means (not illustrated), such as an overhead transfer, an overhead conveyor, or an automatic guided vehicle, or an operator.

An index robot 120 is provided to the index frame 14. A guide rail 124 of which a longitudinal direction is the second direction Y is provided within the index frame 14, and the index robot 120 may be provided to be movable on the guide rail 124. The index robot 120 includes a hand 122 on which the substrate M is placed, and the hand 122 may be provided to be movable forward and backward, rotatable about the third direction Z, and movable along the third direction Z. The plurality of hands 122 is provided while being spaced apart from each other in the up and down direction, and is capable of independently moving forward and backward.

The controller 30 is configured to control the substrate processing apparatus 1. The controller 30 may include a process controller formed of a microprocessor (computer) that executes the control of the substrate processing apparatus 1, a user interface including a keyboard in which an operator performs a command input operation or the like in order to manage the substrate processing apparatus 1, a display for visualizing and displaying an operation situation of the substrate processing apparatus 1, and the like, and a storage unit storing a control program for executing the process executed in the substrate processing apparatus 1 under the control of the process controller or a program, that is, a treating recipe, for executing the process in each component according to various data and treating conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

The controller 30 may control the substrate processing apparatus to perform the substrate processing method described below. For example, the controller 30 may control the components provided to a liquid treating chamber 400 so as to perform the substrate processing method described below.

The treating module 20 includes a buffer unit 200, a transfer chamber 300, and a liquid treating chamber 400. The buffer unit 200 provides a space in which the substrate W loaded into the treating module 20 and the substrate W unloaded from the treating module 20 stay temporarily. The liquid treating chamber 400 performs a liquid treatment process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction is the first direction X. The buffer unit 200 may be disposed between the index module 10 and the transfer chamber 300. The liquid treating chamber 400 may be disposed on a side portion of the transfer chamber 300. The liquid treating chamber 400 may be disposed in the second direction Y. The buffer unit 200 may be located at one end of the transfer chamber 300.

According to the example, the liquid treating chambers 400 are respectively disposed on opposite sides of the transfer chamber 300. At one side of the transfer chamber 300, the liquid treating chambers 400 may be provided in an array of A×B (each of A and B is 1 or a natural number larger than 1) in the first direction X and the third direction Z.

The transfer chamber 300 includes a transfer robot 320. A guide rail 324 having a longitudinal direction in the first direction X is provided in the transfer chamber 300, and the transfer robot 320 may be provided to be movable on the guide rail 324. The transfer robot 320 includes a hand 322 on which the substrate W is placed, and the hand 322 may be provided to be movable forward and backward, rotatable about the third direction Z, and movable along the third direction Z. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed while being spaced apart from each other in the third direction Z. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

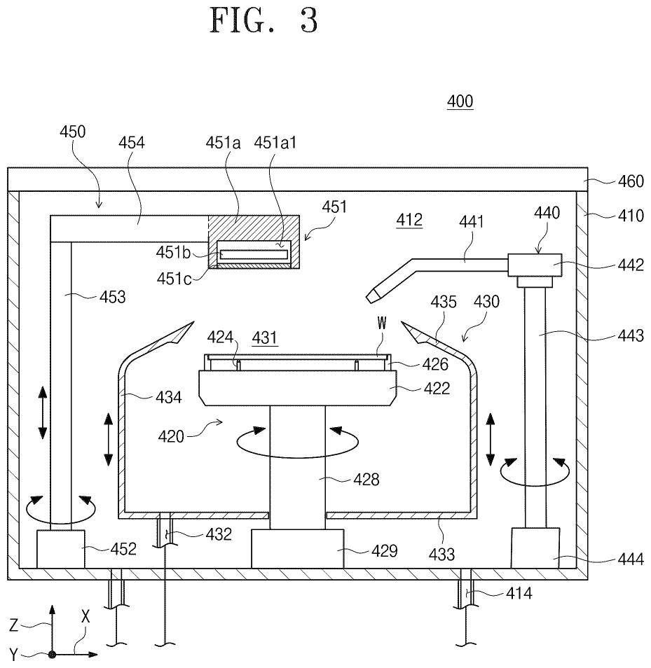

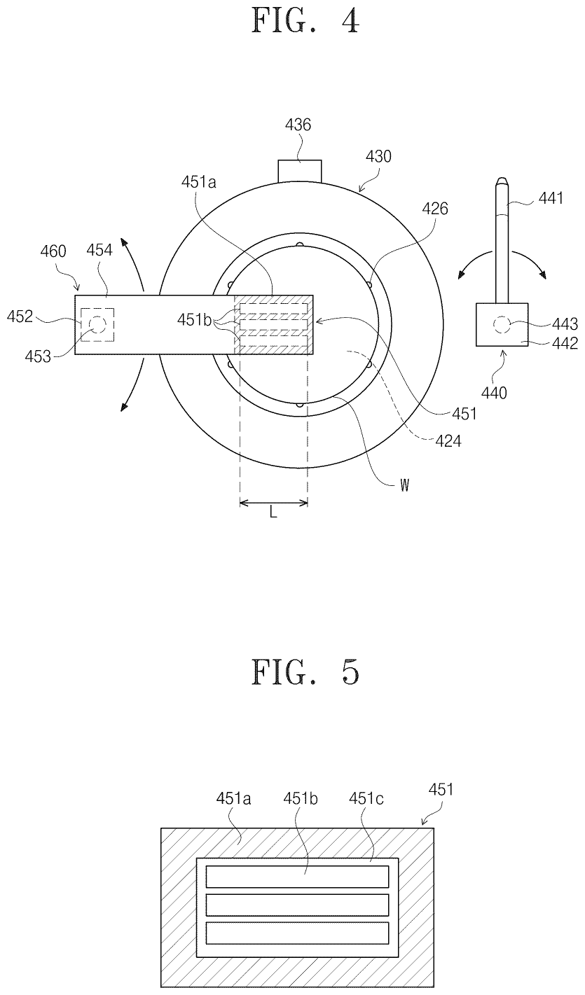

FIG. 3 is a cross-sectional view of the liquid treating chamber of FIG. 2 viewed from the side, FIG. 4 is a top plan view illustrating the liquid treating chamber of FIG. 3 viewed from above, and FIG. 5 is a diagram of a light source module of the liquid treating chamber of FIG. 3 as viewed from below.

Referring to FIGS. 3 to 5, the liquid treating chamber 400 may include a housing 410, a support unit 420, a bowl 430, a nozzle unit 440, a light emission unit 450, and a gas supply unit 460.

The housing 410 may provide an inner space 412. The components for treating the substrate W may be disposed in the inner space 412 of the housing 410. For example, the support unit 420 may support the substrate W in the inner space 412. At least some of the components of the bowl 430, the nozzle unit 440, and the light emission unit 450 to be described below may be provided in the inner space 412. A loading/unloading port (not illustrated) through which the substrate W may be loaded/unloaded may be formed in the housing 410. The loading/unloading port may be selectively opened/closed by a door (not illustrated). Also, an inner wall surface of the housing 410 may be coated with a highly corrosive material with respect to the treatment liquid supplied by the nozzle unit 440.

Also, an exhaust hole 414 may be formed in a bottom surface of the housing 410. The exhaust hole 414 may be connected to an exhaust device, such as a pump that may exhaust the inner space 412. Accordingly, fume that may be generated in the inner space 412 may be exhausted to the outside through the exhaust hole 414.

The supporting unit 420 may support and rotate the substrate W. The support unit 420 may be referred to as a substrate holder. The support unit 420 may support the substrate W in the inner space 412. More specifically, the substrate W may be supported in a treatment space 431 provided by the bowl 430 to be described later.

The support unit 420 may include a spin head 422, a support pin 424, a chuck pin 426, a driving shaft 428, and a driving unit 429. The spin head 422 may be provided as a generally circular plate when viewed from above. The driving shaft 428 that may be rotated by the driving unit 429 may be coupled to a lower portion of the spin head 422. When the driving shaft 428 rotates, the spin head 422 may rotate together with the substrate W. The spin head 422 may include the support pin 424 and the chuck pin 426 so as to support the substrate. A plurality of support pins 424 protrude from an upper surface of the spin head 422 to support the lower surface of the substrate W.

A plurality of chuck pins 426 is disposed at a position farther from the center of the spin head 422, than the support pin 424. The chuck pin 426 may be configured to support a side portion of the substrate W so that the substrate W is not separated from a regular position when the spin head 422 and the substrate W are rotated.

The chuck pin 426 may be provided to be linearly moved between a standby position and a support position along a radial direction of the spin head 422. The standby position may be a position farther from the center of the spin head 422 than the support position. When the substrate W is loaded to or unloaded from the support unit 420 by a robot or the like, the chuck pin 426 is located at the standby position, and when a process is performed on the substrate W, the chuck pin 426 is located at the support position. At the support position, the chuck pin 426 may be in contact with a side portion of the substrate W.

The bowl 430 may have a cylindrical shape with an open top. The bowl 430 may provide the treatment space 431. The substrate W may be treated in the treatment space 431. The bowl 430 may prevent the treatment liquid supplied to the substrate W from being scattered and delivered to the housing 410, the nozzle unit 440, the light emission unit 450, and the gas supply unit 460.

The bowl 430 may have a bottom portion 433, a vertical portion 434, and an inclined portion 435. When viewed from the top, an opening into which the driving shaft 428 may be inserted may be formed in the bottom portion 433. The vertical portion 434 may extend from the bottom portion 433 in the third direction Z. The inclined portion 435 may extend obliquely upward from the vertical portion 434. For example, the inclined portion 435 may extend obliquely in a direction toward a rotation center of the support unit 420. The bottom portion 433 may be formed with a discharge hole 432 through which the treatment liquid supplied by the nozzle unit 440 may be discharged to the outside. Also, the bowl 430 may be coupled to a lifting member 436 and the position of the bowl 430 may be changed along the third direction Z. The lifting member 436 may be a driving device that moves the bowl 430 in the up and down direction. The lifting member 436 may move the bowl 430 upward while the liquid treatment and/or the heat treatment is performed on the substrate M, and may move the bowl 430 downward when the substrate W is loaded into the inner space 412 or the substrate W is unloaded from the inner space 412.

The nozzle unit 440 may supply a treatment liquid onto the substrate W. The nozzle unit 440 may include a nozzle 441, a nozzle fixing body 442, a nozzle rotation shaft 443, and a nozzle rotation driver 444.

The nozzle 441 may supply the treatment liquid to the substrate M supported by the support unit 420. The treatment liquid may be a liquid that does not contain chemicals. For example, the treatment liquid may be Deionized Water (DIW). Optionally, the treatment liquid may be Ozone-Deionized Water (O₃DIW). One end of the nozzle 411 may be connected to the nozzle fixing body 442, and the other end thereof may extend in a direction from the nozzle fixing body 442 toward the substrate W. Furthermore, the nozzle 411 may be bent at a predetermined angle and extended in a direction toward the substrate W supported by the support unit 420.

The nozzle fixing body 442 may fix and support the nozzle 441. The nozzle fixing body 442 may be connected to the rotation shaft 443 that rotates about the third direction Z by the nozzle rotation driver 444. When the nozzle rotation driver 444 rotates the rotation shaft 443, the nozzle fixing body 442 may be rotated about the third direction Z. Accordingly, a discharge port of the nozzle 441 may be moved between a liquid supply position, which is a position for supplying the treatment liquid to the substrate W, and a standby position, which is a position where the treatment liquid is not supplied to the substrate W. Furthermore, the nozzle rotation driver 444 may be configured to include a motor or the like.

The light emission unit 450 may be configured to emit light onto the substrate W. The light emission unit 450 may emit light onto the substrate W supported by the support unit 420 to remove a film on the substrate W. The removed film may be an organic film. For example, the film may be a photoresist film. Also, the film may be a photoresist film subjected to ion implantation.

The light emission unit 450 may include a light source module 451, a module movement driver 452, a module rotation shaft 453, and a module arm 454.

The light source module 451 may emit light to the substrate W. The light source module 451 may include a body 451a, a light source 451b, and a cover 451c. The body 451a may have a light source space 451al in which the light source 451b may be disposed. The light source space 451al of the body 451a may be a space that is open downward.

At least one light source 451b may be provided in the light source space 451al. For example, a plurality of light sources 451b may be disposed in the light source space 451al. The light sources 451b may be arranged side by side in a horizontal direction, for example, the second direction Y.

The cover 451c may seal the light source space 451al so that the light source 451b disposed in the light source space 451al is not exposed to the treatment liquid. The cover 451c may be made of a transparent material. For example, the cover 451c may be made of a transparent quartz material. Furthermore, the body 451a may be made of an opaque material so that light emitted by the light source 451b may be concentrated and emitted downward. For example, the body 451a may be made of an opaque metal material including aluminum or the like.

The light source 451b may be a lamp that emits light of a wavelength band for removing an organic material, for example, a photoresist, on the substrate W. The length L of the light source 451b may be substantially the same as a radius of the substrate W, which is an object to be treated. Accordingly, when the light source 451b rotates the substrate W while emitting light to the substrate W, light irradiated by the light source 451b may be transmitted to the entire area of the substrate W relatively uniformly.

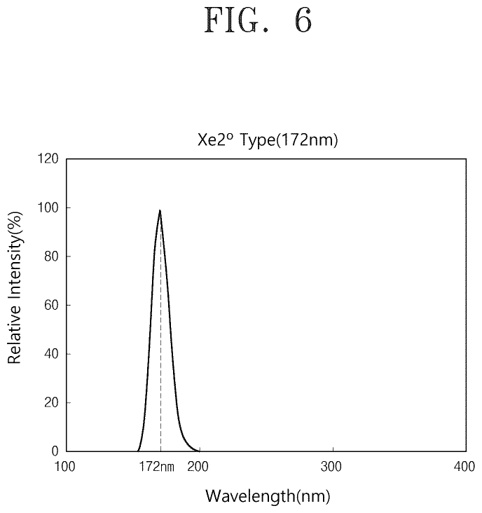

Also, the light source 451b may be an excimer UV lamp. As illustrated in FIG. 6, the light source 451b may be an excimer UV lamp configured to emit light having a high intensity in a wavelength band of 172 nm. The light energy irradiated by the light source 451b, which is an excimer UV lamp, may be about 698 kJ/mol. Since the light source 451b, which is an excimer UV lamp, has high light intensity and high light energy compared to a general UV lamp, there is a technical advantage of effectively destroying multiple bonds of a photoresist including a C-rich crust layer.

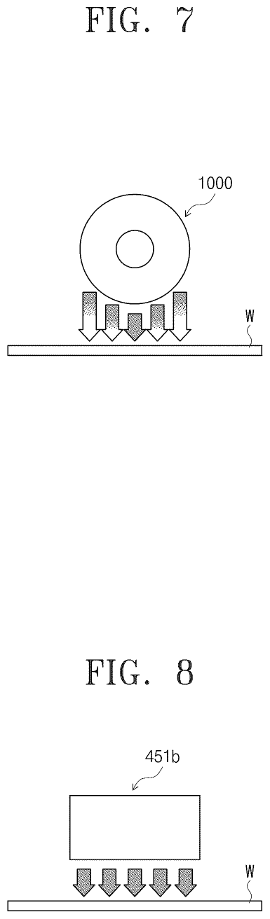

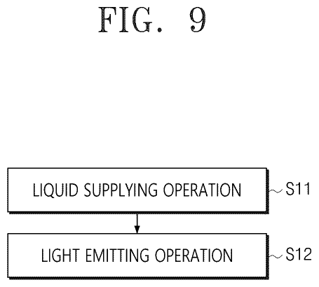

FIGS. 7 and 8 are diagrams for describing a light irradiation effect according to a shape of the light source of FIG. 3.

Referring to FIG. 7, an existing light source 1000 has a circular tubular cross-section. Accordingly, the distance between the lower surface of the light source 1000 and the upper surface of the substrate W may not be constant. Accordingly, the intensity of light emitted by the light source 1000 and transferred to the substrate W may be different for each area of the light source 1000.

Referring to FIG. 8, the light source 451b according to the embodiment of the present invention may have a rectangular tubular cross-section, and a distance between the lower surface of the light source 451b and the upper surface of the substrate W may be constant. Accordingly, intensity of light emitted by the light source 451b and transferred to the substrate W may be constant regardless of the position of the light source 451b. That is, the light source 451b may irradiate light onto the substrate W relatively and uniformly.

In addition, in the case of the above-described excimer UV lamp, light of a short wavelength of high energy is emitted, and the light is reflected with oxygen when it meets oxygen dissolved in the atmosphere or the treatment liquid to consume light energy. For example, in the case of 172 nm, in the emission distance of 8 mm in the atmosphere, the emission intensity decreases to about 1/10 of the emission intensity. In other words, when the cross-section of the existing light source 1000 is a circular tube, as described above, a distance between the central portion of the light source 1000 and the substrate W may be slightly different from a distance between the edge portion of the light source 1000 and the substrate W. However, even with such a slight difference in distance, the emission intensity of light that may be transmitted to the substrate W may be significantly different. Therefore, the fact that the light source 451b of the present invention has the cross-section of the rectangular tubular shape acts as an important factor in emitting light of relatively uniform intensity to the substrate W.

Referring back to FIGS. 3 to 5, the module rotation shaft 453 may be rotated along the third direction Z by the module movement driver 452 including a motor or the like. In addition, the module rotation shaft 453 may be configured to move vertically along the third direction Z by a linear motor that may be included in the module movement driver 452. One end of the module rotation shaft 453 may be connected to the module movement driver 452, and the other end thereof may be connected to the module arm 454. The light source module 451 described above may be coupled to the module arm 454. The light source module 451 may be moved in the circumferential direction of an imaginary circle having the module arm 454 as a radius in the third direction Z that serves as the rotation shaft by the module movement driver 452, the module rotation shaft 453, and/or the module arm 454.

The gas supply unit 460 may supply gas to the inner space 412. The gas supply unit 460 may include a fan filter. The gas supplied by the gas supply unit 460 may be inert gas, such as clean air, clean dry air (CDA) and/or nitrogen gas. CDA may be air having a relatively low humidity and/or temperature compared to clean air. The user may adjust the type of gas supplied to the inner space 412 and/or the supply flow rate per unit time through the controller 30. The gas supply unit 460 may supply gas to the inner space 412 in a down flow form. The oxygen concentration in the inner space 412 may vary according to the type of gas supplied by the gas supply unit 460 and/or the supply flow rate per unit time.

Hereinafter, a substrate processing method according to an exemplary embodiment of the present invention will be described. The substrate processing method described below may be implemented by the processing apparatus 1. Specifically, the substrate processing method may be implemented by the liquid treating chamber 400 of the substrate processing apparatus 1. In order to implement the substrate processing method described below in the liquid treating chamber 400, the controller 30 of the substrate processing apparatus 1 may generate a control signal for controlling components of the liquid treating chamber 400. For example, the controller 30 may generate a control signal for controlling at least one of the support unit 420, the bowl 430, the nozzle unit 440, the light emission unit 450 and the gas supply unit 460.

FIG. 9 is a flowchart illustrating a substrate processing method according to an embodiment of the present invention.

Referring to FIG. 9, in the substrate processing method according to the embodiment of the present invention, a liquid supplying operation S11 and a light emitting operation S12 may be performed. The liquid supplying operation S11 and the light emitting operation S12 may be sequentially performed.

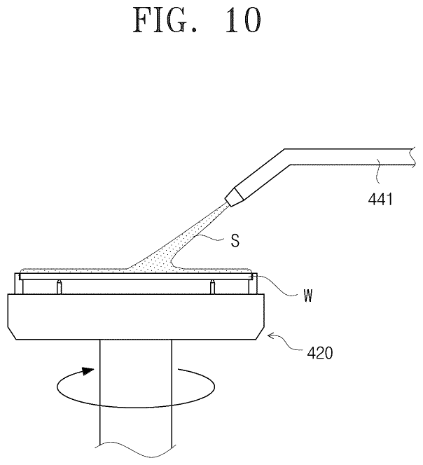

FIG. 10 is a diagram illustrating a state of the liquid treating chamber performing the liquid supplying operation of FIG. 9.

Referring to FIG. 10, in the liquid supplying operation S11, the nozzle 441 of the nozzle unit 440 may supply a treatment liquid S to the rotating substrate W supported by the support unit 420. The treatment liquid S supplied by the nozzle unit 440 may include an oxygen atom O. For example, the treatment liquid S supplied in the liquid supplying operation S11 may include deionized water DIW and/or ozone water. Also, a part of dissolved oxygen may be present in the treatment liquid S. In the liquid supplying operation S11, the treatment liquid S is supplied to the rotating substrate W to form a liquid film on the substrate W, and the upper surface of the substrate W may be wetted by the formed liquid film.

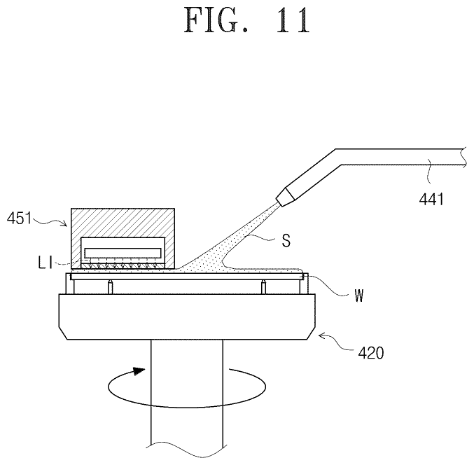

FIG. 11 is a diagram illustrating a state of the liquid treating chamber performing the light emitting operation of FIG. 9.

Referring to FIG. 11, in the light emitting operation S12, the light source module 451 may emit light LI to the substrate W supported by the support unit 420. The light LI may be provided as a high energy short wavelength. The light source module 451 including the excimer UV lamp may emit light LI having a wavelength of about 172 nm to the substrate W. In this case, an organic material, such as a photoresist, that may be present on the substrate W may be removed from the substrate W by the light LI. An organic material, such as a photoresist, may be removed in an in-situ activation form through generation of O₃ and OH. The light energy of the light LI may be transferred to the organic material and the treatment liquid S provided on the substrate W. The light energy transferred to the organic material may destroy multiple bonds of the organic material. The organic material may be oxidized and degraded by reacting the organic material, from which multiple bonds are destroyed, with O₃ and OH radicals.

The generation of O₃, OH· may be caused by the following mechanisms.

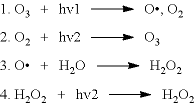

hv1 and hv2 may mean photon energy.

In the light emitting operation S12, the treatment liquid S supplied in the liquid supplying operation S11 may be continuously supplied. Accordingly, the liquid film formed on the substrate W may be maintained. In addition, in the light emitting operation S12, the substrate W may continue to rotate by the support unit 420. Further, in the light emitting operation S12, light LI may be emitted in a state in which the light source module 451 is in contact with the liquid film formed by the treatment liquid S. In this case, the distance between the light source module 451, specifically the light source 451b, and the upper surface of the substrate W is 10 mm or less, more preferably 5 mm or less, and more preferably 2 mm or less, but in a state in which the lower surface of the body 451a of the light source module 451 and the substrate W are spaced apart from each other, the light source module 451 may emit the light LI.

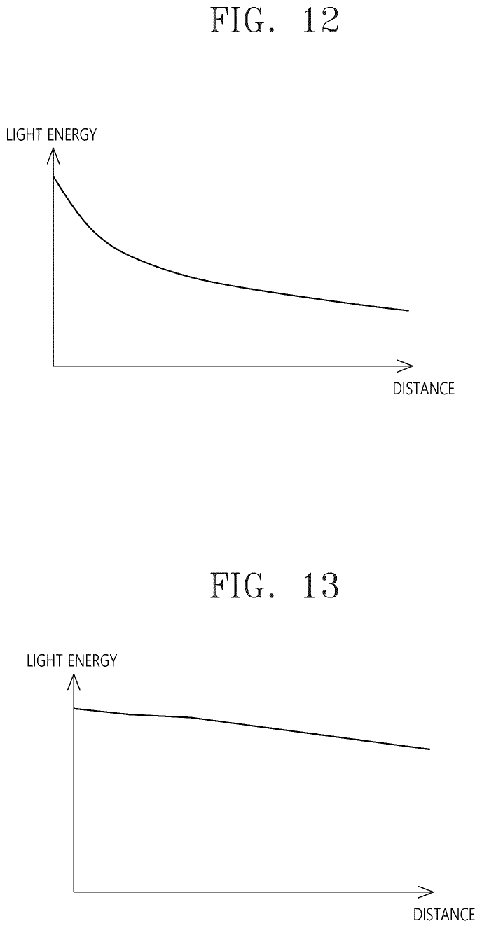

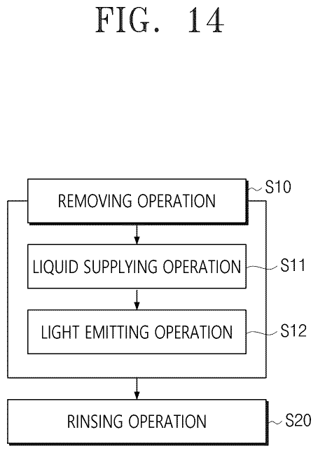

FIGS. 12 and 13 are graphs illustrating an attenuation rate in a process of transmitting light energy emitted by the light source module to the substrate.

FIG. 12 illustrates a change in light energy of the light source module 451 according to a distance between the light source module 451 and the substrate W in a general atmosphere. FIG. 13 illustrates a change in light energy of the light source module 451 according to a distance between the light source module 451 and the substrate W in a nitrogen atmosphere.

As illustrated in FIG. 12, as a distance between the substrate W and the light source module 451 increases, light energy attenuation increases. This is because light LI of a high energy short wavelength reacts with oxygen in the atmosphere and consumes light energy.

As illustrated in FIG. 13, in a nitrogen atmosphere, light energy attenuation occurs less than in a general atmosphere. This is because in a nitrogen atmosphere, a ratio of oxygen capable of reacting with light LI is relatively small, and a ratio of nitrogen which is inert gas which is difficult to react with light LI is relatively large. However, even in a nitrogen atmosphere, light energy attenuation occurs as the distance between the substrate W and the light source module 451 increases.

Referring back to FIG. 11, in the present invention, light LI is emitted in a state in which the light source module 451 is in contact with the liquid film formed by the treatment liquid S supplied onto the substrate W. As a result, when the substrate W and the light source module 451 are separated from each other, light energy attenuation occurs largely, and thus light energy of the light LI is not properly transferred to the substrate W, thereby not effectively removing the organic material. In addition, since the treatment liquid S supplied onto the substrate W is the treatment liquid S containing oxygen O as described above, the treatment liquid S also serves as a kind of precursor for generating O₃, OH· (radical). In short, the light source module 451 of the present invention may further maximize the efficiency of removing organic substances, such as photoresists, on the substrate W by irradiating light LI while being in contact with the treatment liquid S supplied onto the substrate W, suppressing the attenuation of the energy of light LI as much as possible, and effectively generating O₃ and OH radicals through the oxygen medium contained in the treatment liquid S.

Table 1 below is the result of evaluating the removal efficiency when the photoresist for ArF is removed using an excimer UV Lamp. Table 2 is the result of evaluating the removal efficiency when the photoresist for KrF is removed using an excimer UV Lamp.

TABLE 1

| ArF | RT | RT + H₂O Wetting |
|---|---|---|
| 1 min | Good | Good |
| 5 min | Good | Good |

TABLE 2

| KrF | RT | RT + H₂O Wetting |
|---|---|---|
| 1 min | — | Partially removed |
| 5 min | Partially removed | Good |

Investigating Table 1 above, the photoresist for ArF shows high removal efficiency in all cases including the case where light LI is emitted for 1 min under the room temperature (RT) condition, the case where light LI is emitted for 5 min under the RT condition, the case where light LI is emitted for 1 min under the RT condition while the substrate W is wetted by H₂O₂, and the case where light LI is emitted for 5 min under the RT condition while the substrate W is wetted by H₂O.

However, investigating Table 2 above, when light LI is emitted for 5 min under the RT condition, some photoresists are removed, whereas photoresists for KrF show high removal efficiency when light LI is emitted for 5 min under the RT condition while the substrate W is wetted by H₂O. In short, even under the same condition, it can be seen that the substrate W has more improved organic material removal efficiency when the substrate W is wetted by H₂O.

In addition, process by-products, which are organic materials removed from the substrate W by O₃ and OH radicals, may be scattered and removed from the substrate W by the treatment liquid S continuously supplied in the light emitting operation S12 and the rotation of the substrate W.

FIG. 14 is a flowchart illustrating a substrate processing method according to another embodiment of the present invention.

Referring to FIG. 14, a user may further perform an additional rinsing operation S20 after the light emitting operation S12 as needed. For example, after a removing operation S10 including the liquid supplying operation S11 and the light emitting operation S12, the rinsing operation S20 of supplying a rinsing liquid, such as DIW, to the rotating substrate W may be additionally performed. By additionally performing the rinsing operation S20, some process by-products which may remain on the substrate W may be removed from the substrate W.

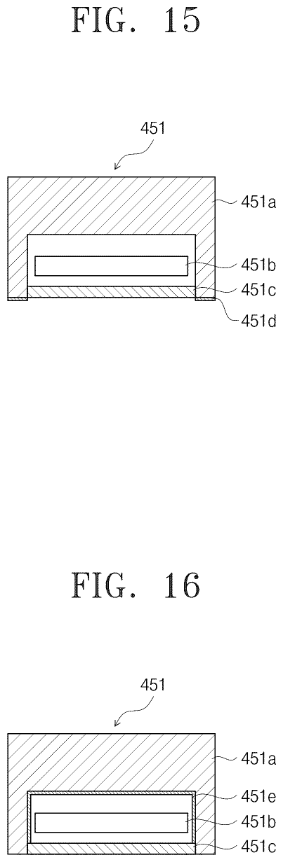

FIGS. 15 to 17 are diagrams for describing a light source module according to another embodiment of the present invention.

The light source module 451 according to another embodiment of FIG. 15 may further include a hydrophobic coating portion 451d. The hydrophobic coating portion 451d may be provided in a bottom edge region of the body 451a. When the light source module 451 is in contact with the treatment liquid S, the liquid film formed by the treatment liquid S may ascend along the bottom surface and the side surface of the body 451a by adhesion force between the treatment liquid S and the surface of the body 451a. In this case, the liquid film of the treatment liquid S provided between the light source module 451 and the substrate W may become relatively non-uniform. To improve the problem, since the light source module 451 according to another embodiment includes the hydrophobic coating portion 451d, it is possible to prevent the treatment liquid S from ascending along the bottom surface and the side surface of the body 451a.

The light source module 451 according to another embodiment of FIG. 16 may further include a reflective coating portion 451e. The reflective coating portion 451e may be provided on an inner wall of the body 451a defining the light source space 451a1. The reflective coating portion 451e may be made of a material including gold. The light LI emitted by the light source 451b may be radiated in a lateral direction or an upward direction, and the reflective coating portion 451e reflects the light LI that may be radiated in a lateral direction or an upward direction to help the light LI be concentrated in a direction toward the substrate W.

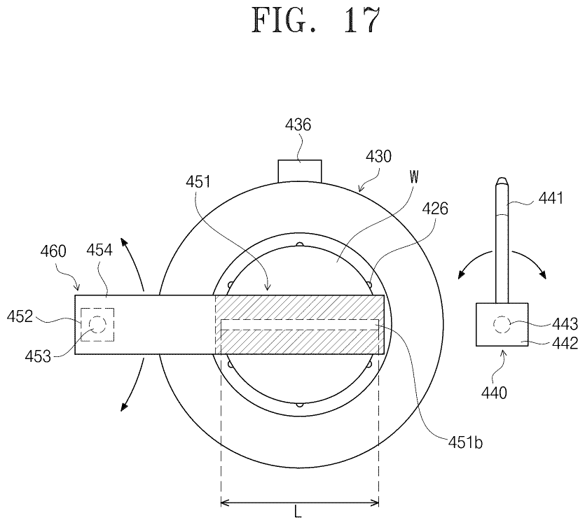

A length L of the light source 451b of the light source module 451 according to another embodiment of FIG. 17 may be substantially the same as the diameter of the substrate W. In this case, there is an advantage that more light energy may be transferred per unit time onto the substrate W.

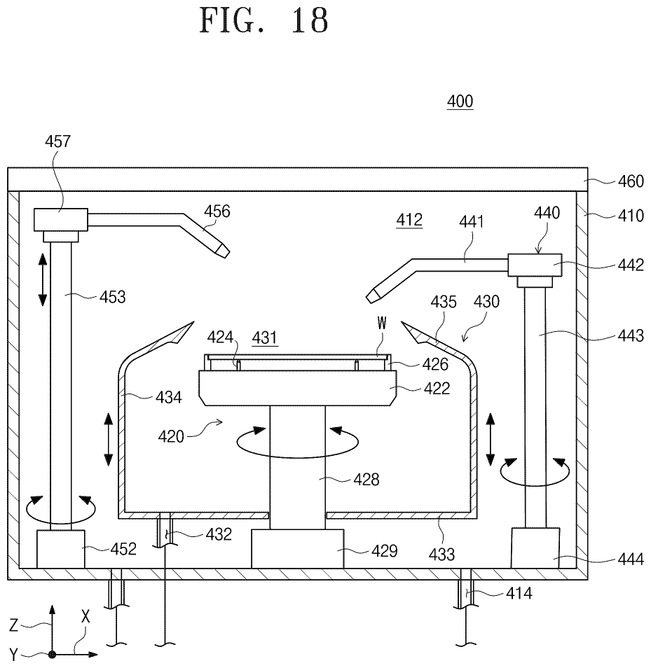

FIG. 18 is a diagram illustrating a state in which a nozzle for supplying a treatment liquid is installed instead of the light source module of the present invention.

Referring to FIG. 18, the light source module 451 and the module arm 454 of the light emission unit 450 described above may be detachably provided. Therefore, the user may separate the light source module 451 and the module arm 454 from the module rotation shaft 453. In addition, a nozzle fixing body 457 and a nozzle 456 may be installed on the module rotation shaft 453. That is, an additional nozzle unit may be provided separately from the nozzle unit 440 described above according to a user's selection.

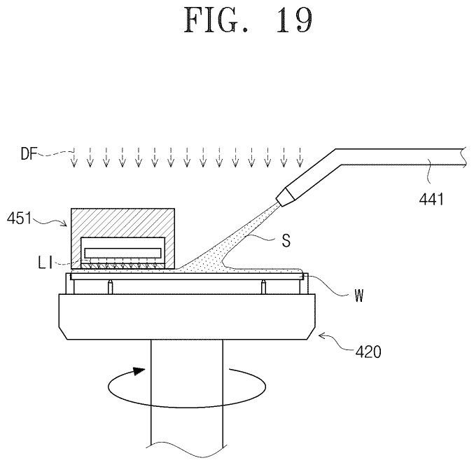

FIG. 19 is a diagram illustrating the liquid treating chamber performing he light emitting operation according to another embodiment of the present invention.

Referring to FIG. 19, in the above-described light emitting operation S12, even if the light source module 451 is in contact with the treatment liquid S and emits the light LI, at least a part of the light LI may not be fully transferred to the treatment liquid S and may be emitted into the atmosphere. In this case, the light energy may be unnecessarily consumed. Accordingly, in the light emitting operation S12, the gas supply unit 460 may supply inert gas, which may be nitrogen gas, to the inner space 412 in the form of a downflow DF. Accordingly, the atmosphere of the inner space 412 may be converted to a nitrogen atmosphere. Accordingly, it is also possible to maximally suppress the consumption of light energy in the atmosphere. Also, the downflow DF is supplied from the middle of the liquid supplying operation S11, and before the light emitting operation S12 starts, the atmosphere of the inner space 412 may be converted to a nitrogen atmosphere. In addition, the supply of the inert gas may be stopped according to the time point at which the light emitting operation S12 ends.

In the above-described example, the present invention has been described based on the case where the position of the light source module 451 is provided to be changeable, and thus the light source module 451 is in contact with the liquid film formed by the treatment liquid S as an example, but is not limited thereto.

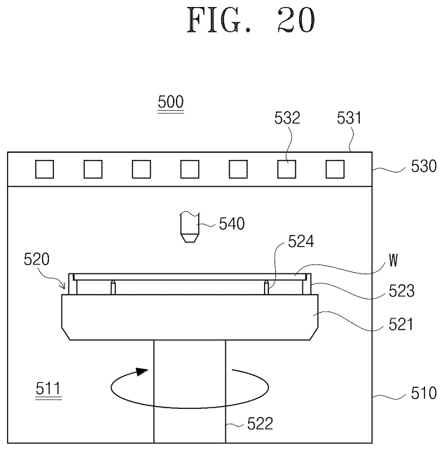

For example, as illustrated in FIG. 20, a liquid treating chamber 500 according to another embodiment of the present invention may include a housing 510 that provides an inner space 511, a support unit 520 that supports and rotates a substrate W in the inner space 511, a nozzle 540 that supplies a treatment liquid S to the substrate W, and a light source module 530 that emits light LI to the substrate W supported by the support unit 520.

Similar to the support unit 420 described above, the support unit 520 may include a spin head 521, a rotation shaft 522, a chuck pin 523, and a support pin 524. Furthermore, the light source module 530 may include a light source 532 which is an excimer UV lamp, and a body 531 which provides the light source 532 therein.

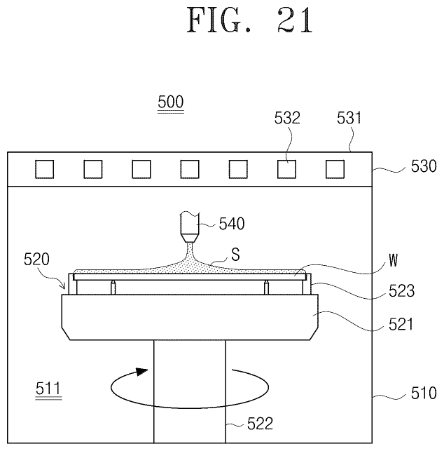

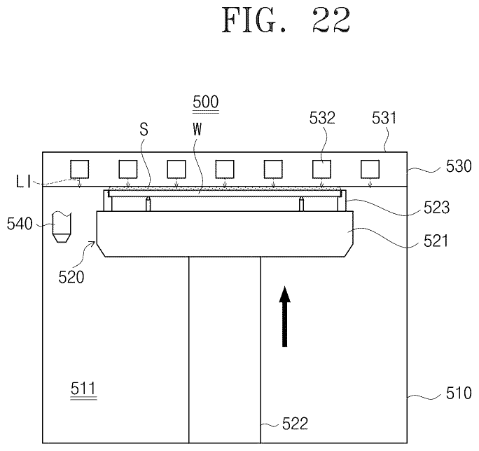

FIGS. 21 to 22 are diagrams illustrating a state in which a liquid treating chamber treats a substrate according to another embodiment.

As illustrated in FIG. 21, the nozzle 540 may supply the treatment liquid S to the rotating substrate W to form a liquid film. Thereafter, the support unit 520 may raise the substrate W to make the liquid film formed by the treatment liquid S be in contact with the light source module 530. Further, as illustrated in FIG. 22, after the light source module 530 comes into contact with the liquid film, the light source module 530 may emit light LI to remove an organic material, such as a photoresist, on the substrate W.

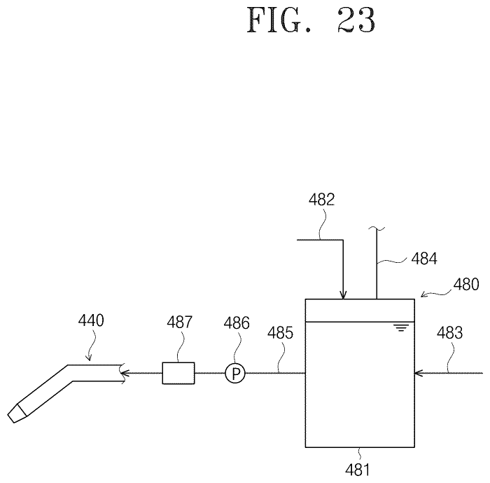

FIG. 23 is a diagram schematically illustrating a liquid supply unit that may be provided in the substrate processing apparatus of the present invention.

As described above, the removal of the photoresist may be performed by O₃ and OH radicals that may be generated by reacting the high-energy short-wavelength light LI with oxygen. Accordingly, when the amount of dissolved oxygen contained in the treatment liquid S and/or the output of the light LI are controlled, the amount of O₃ and OH radicals generated may be controlled, thereby controlling the efficiency of removing the photoresist. For example, when the amount of dissolved oxygen contained in the treatment liquid S and/or the output of light LI are increased, the efficiency of removing the photoresist may be increased, and when the amount of dissolved oxygen contained in the treatment liquid S and/or the output of the light LI is decreased, the efficiency of removing the photoresist may be lowered.

Accordingly, the substrate processing apparatus 1 of the present invention may include a liquid supply unit 480 capable of supplying the treatment liquid S through the nozzle unit 440 and controlling the amount of dissolved oxygen in the treatment liquid S.

The liquid supply unit 480 may include a liquid supply source 481, such as a tank, a treatment liquid supply line 482 for supplying deionized water and/or ozone water to the liquid supply source 481, an oxygen supply line 483 for supplying oxygen to the treatment liquid stored in the liquid supply source 481, a discharge line 484 for discharging bubbles in the liquid supply source 481 or discharging the atmosphere in the liquid supply source 481 to control the pressure in the liquid supply source 481, a treatment liquid transfer line 485 for delivering the treatment liquid in the liquid supply source 481 to the nozzle 441, a pump 486 for generating the flow of the treatment liquid in the treatment liquid transfer line 485, and a heater 487 for controlling the temperature of the treatment liquid.

When the amount of dissolved oxygen in the treatment liquid S is to be increased, the controller 30 may transmit a control signal for supplying oxygen from the oxygen supply line 483 to the liquid supply source 481 or increasing the supply flow rate of the supplied oxygen per unit time to the liquid supply unit 480. Alternatively, when the amount of dissolved oxygen in the treatment liquid S is to be lowered, the controller 30 may transmit a control signal for stopping the oxygen supply from the oxygen supply line to the liquid supply source 481 or lowering the supply flow rate of the supplied oxygen per unit time to the liquid supply unit 480.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. A method of processing a substrate, the method comprising:
supplying a treatment liquid containing oxygen atoms to a rotating substrate, and emitting, by a light source module, light to the substrate in a state where a liquid film formed by the supplied treatment liquid is in contact with the light source module to remove an organic material on the substrate.

2. The method of claim 1, wherein the light source module includes a UV lamp that emits the light.

3. The method of claim 2, wherein the light source module includes an excimer UV lamp that emits the light, and the excimer UV lamp emits the light in a wavelength range of 172 nm.

4. The method of claim 3, wherein the excimer UV lamp has a cross-section of a square tubular shape.

5. The method of claim 1, wherein while the light source module emits the light to the substrate, the treatment liquid is continuously supplied to the substrate.

6. The method of claim 5, wherein while the light source module emits the light to the substrate, the substrate continues to rotate.

7. The method of claim 1, wherein the light source module is located apart from an upper surface of the substrate while light source module emits the light, a distance between a light source, which is included in the light source module and emits the light, and the upper surface of the substrate is 10 mm or less.

8. The method of claim 1, wherein the treatment liquid is deionized water and/or ozone water, and
the organic material is a photoresist.

9. The method of claim 8, wherein the organic material is an ion-implanted photoresist.

10. The method of claim 1, wherein, to control efficiency of removing the organic material, the amount of oxygen supplied to the treatment liquid is controlled before the treatment liquid is supplied to the substrate to control the amount of dissolved oxygen in the treatment liquid.

11. The method of claim 10, wherein in a case of increasing the efficiency of removing the organic material, the amount of oxygen supplied to the treatment liquid is increased, and
in a case of lowering the efficiency of removing the organic material, the amount of oxygen supplied to the treatment liquid is decreased.

12. A manufacturing method, comprising:
supplying a treatment liquid containing oxygen to a substrate provided with a photoresist, wherein an excimer UV lamp emits light to the treatment liquid to generate ozone and/or OH radicals, and the ozone and/or OH radicals decompose the photoresist, and
the light source module that emits the light emits the light in a state of being in contact with a liquid formed by the treatment liquid.

13. The manufacturing method of claim 12, wherein while the light is emitted,
the supply of the treatment liquid continues to maintain the liquid film.

14. The manufacturing method of claim 13, wherein while the light is emitted,
the substrate continues to rotate.

15. The manufacturing method of claim 12, wherein the treatment liquid is deionized water and/or ozone water.

16. The manufacturing method of claim 12, wherein the photoresist is ion-implanted to form a C-rich crust layer on a surface thereof.

17.-20. (canceled)
